(19) United States
(12) Patent Application Publication
(10) Pub. No.: US 2013/0248611 A1
(43) Pub. Date: Sep. 26, 2013

(54) Epitaxial Deposition Apparatus, Gas Injectors, and Chemical Vapor Management System Associated Therewith

(71) Applicants: Richard Ares, Sherbrooke (CA); Laurent Isnard, Sherbrooke (CA)

(72) Inventors: Richard Ares, Sherbrooke (CA); Laurent Isnard, Sherbrooke (CA)

(73) Assignee: Socpra Sciences Et Genie S.E.C., Sherbrooke, QC (CA)

(21) Appl. No.: 13/990,299

(22) PCT Filed: Nov. 30, 2011
(86) PCT No.: PCT/CA2011/001331

§ 371 Date: May 29, 2013

Related U.S. Application Data
(60) Provisional application No. 61/418,104, filed on Nov. 30, 2010.

(51) Int. Cl. C23C 16/455

(52) U.S. Cl. CPC C23C 16/45563
USPC 239/1; 137/561 A; 137/1

(57) ABSTRACT

An epitaxial deposition apparatus comprises a deposition chamber with at least one gas injector having a gas injection surface and a substrate support having a deposition surface; and at least one vacuum pump having a gas aperture in fluid communication with the deposition chamber and facing the gas injection surface of the at least one gas injector, the substrate support being inter-posed between the at least one gas injector and the gas aperture of the at least one vacuum pump. The invention also relates to an epitaxial deposition gas injector and a nozzle for an epitaxial deposition gas injector. Furthermore, the invention relates to a gas supply and handling system for an epitaxial deposition apparatus.

### CROSS-REFERENCE TO RELATED APPLICATIONS

This application claims priority under 35USC§119(e) of U.S. provisional patent application 61/418,104 filed on Nov. 30, 2011, the specification of which is hereby incorporated by reference.

### TECHNICAL FIELD OF THE INVENTION

The technical field relates to an epitaxial deposition apparatus and, more particularly, to an epitaxial deposition apparatus for vapor phase epitaxy (VPE) and its associated chemical vapor management system and gas injector. It also relates to a method for epitaxial deposition and gas supply during epitaxial deposition processes.

### BACKGROUND

Epitaxial growth of semiconductor thin films has been used to fabricate systems for a wide variety of applications in electronics and photonics, over many years. The techniques that are used to produce nucleation of crystalline materials over the surface of a crystalline substrate are numerous. For instance, vapor phase epitaxy (VPE) processes provide high level of purity and film quality. VPE uses chemical molecules or atoms in gaseous form for deposition over the surface of a heated substrate during the epitaxy process. Thin layers of high purity materials are deposited on the crystalline substrate. The deposited layer has the same structure than the substrate surface, i.e. the deposited layer atoms are aligned with the substrate atoms.

In VPE and more particularly ultra-high vacuum (UHV)-based epitaxial growth techniques, the substrate is inserted in a vacuum chamber. Gases are extracted from the chamber with pumps until the pressure within the chamber is in a high or ultra-high vacuum range (High vacuum range: about 1×10⁻³ Torr to about 1×10⁻⁹ Torr 100 mPa to 100 nPa; Ultra-high vacuum range: about 1×10⁻⁹ Torr to about 1×10⁻¹² Torr; 100 nPa to 100 pPa). In these pressure ranges, the ambient pressure is so low and gas is so rarified that the gas molecules remaining in the chamber do not collide or very rarely do so and travel in the chamber along a substantially straight line. Some molecules hit the substrate surface. The epitaxy process requires that the quantity of molecules that hit the substrate surface is substantially uniform along the substrate surface. Typically the industry standard requires a variation below 1% for several parameters over the surface of the substrate.

There is always a need to reduce the production costs while simultaneously maintaining or increasing the resulting product quality.

### BRIEF SUMMARY OF THE INVENTION

It is therefore an aim of the present invention to address the above mentioned issues.

According to a general aspect, there is provided an epitaxial deposition apparatus comprising: a deposition chamber with at least one gas injector having a gas injection surface and a substrate support having a deposition surface; and at least one vacuum pump having an aperture in fluid communication with the deposition chamber and aligned with the gas injection surface of the at least one gas injector, the substrate support being interposed between the at least one gas injector and the aperture of the at least one vacuum pump.

According to another general aspect, there is provided an epitaxial deposition gas injector comprising: a circular hollow body having a gas inlet located at a proximal end of the body and an opposed distal end and defining an internal gas conduit; at least one partition wall extending in the internal conduit and dividing the internal gas conduit into a conduit section and an outer conduit section, the partition wall being configured to divide an inlet gas flux into two gas flux portions traveling separately towards the distal end in the outer conduit and back towards the proximal end in the conduit.

According to still another general aspect, there is provided an epitaxial deposition apparatus having a reactive gas injector in combination with a gas supply and handling system, the gas supply and handling system comprising: at least two gas supplies, each one of the gas supplies having a first gas conduit connected and in fluid communication with a respective one of the gas supplies; and a gas injector conduit operatively connected to the reactive gas injector, the gas conduit injector being in fluid communication with the first gas conduits.

According to a further general aspect, there is provided a gas supply and handling system for an epitaxial deposition apparatus having a gas injector, the gas supply and handling system comprising: a housing defining a chamber and having a partition wall extending therein and separating the chamber into two sections; at least one gas supply mounted in a first one of the chamber section having a gas conduit connected thereto and extending through the partition wall, the gas conduit being in a controllable fluid communication with the gas injector of the epitaxial deposition apparatus; a heating system configured to heat air contained in the chamber; and a control system operatively connected to the heating system and configured to maintain the temperature of the first one of the chamber section at a first temperature and the temperature of the second one of the chamber section at a second temperature higher than the first temperature.

According to a further general aspect, there is provided a gas supply and handling system for a gas supply and handling system for an epitaxial deposition apparatus having a gas injector, the gas supply and handling system comprising: a housing defining a chamber; a gas supply and handling assembly including at least one gas supply and at least one gas conduit connected to the gas supply mounted in the chamber, the gas conduit being in fluid communication with the gas injector of the epitaxial deposition apparatus; and a heating system configured to heat air contained in the chamber and the at least one gas conduit extending in the chamber.

According to another general aspect, there is provided an epitaxial deposition apparatus comprising: a deposition chamber with at least one gas injector having a gas injection surface and a substrate support having a deposition surface; and at least one vacuum pump having a gas aperture in fluid communication with the deposition chamber and facing the gas injection surface of the at least one gas injector, the substrate support being interposed between the at least one gas injector and the gas aperture of the at least one vacuum pump.

According to still another general aspect, there is provided an epitaxial deposition apparatus comprising: a deposition chamber with at least one gas injector configured to propel a gas along a gas flux path in the deposition chamber, and a substrate support having a deposition surface; and at least one vacuum pump having a gas aperture in fluid communication with the deposition chamber, the gas flux path being directed towards the gas aperture of at least one vacuum pump with the substrate support being mounted in the gas flux path between the gas injector and the vacuum pump.

In an embodiment, the at least one gas injector propels a gas flux in the deposition chamber along a gas flux path and the gas aperture of the at least one vacuum pump is positioned to accept a majority of the gas flux traveling along the gas flux path. The gas aperture of the at least one vacuum pump can be positioned to accept substantially an entirety of the gas flux traveling along the gas flux path.

In an embodiment, the at least one gas injector propels a gas flux with at least one of a normal incidence injection and a grazing incidence injection with respect to the deposition surface of the substrate support. At least one of the gas injector(s) can propel a gas flux with a normal incidence injection wherein the injection surface of the gas injector is substantially parallel to the deposition surface of the substrate support. The gas injector can be positioned substantially centered with at least one of the deposition surface of the substrate support and the gas aperture of the vacuum pump. At least one of the gas injectors can propel a gas flux with a grazing incidence injection wherein the injection surface of the gas injector defines an angle above 0° and below 90° with the deposition surface of the substrate support. Furthermore, at least one of the gas injectors can propel a gas flux with a normal incidence injection wherein the injection surface of the injector is substantially parallel to the deposition surface of the substrate support and at least one of the gas injectors can propel a gas flux with a grazing incidence injection wherein the injection surface of the injector defines an angle above 0° and below 90° with the deposition surface of the substrate support.

In an embodiment, at least one gas injector comprises an elongated nozzle.

In an embodiment, the gas injector comprises a gas injection surface defined by a plurality of gas injection apertures and the gas flux path extends between the gas injection surface and the gas aperture of the at least one vacuum pump. The gas aperture of the vacuum pump can face the gas injection surface of the at least one gas injector.

According to still another general aspect, there is provided a method of epitaxial deposition, comprising: injecting a flux of gas along an injected gas path in a deposition chamber with a gas injector; depositing molecules contained in the injected gas flux on a substrate positioned in the injected gas path; and withdrawing at least a fraction of a remainder of the gas flux with a vacuum pump having a gas aperture facing the injected gas path and mounted downstream of the substrate along the injected gas path.

In an embodiment, the gas aperture of the vacuum pump faces a gas injection surface of the gas injector.

In an embodiment, the step of “injecting” comprises directing the gas flux towards the gas aperture of at least one vacuum pump. In an embodiment, the step of “injecting” is carried out with at least one of a normal incidence injection and a grazing incidence injection with the substrate. The step of “injecting” can be carried out with a normal incidence injection wherein a gas injection surface of the gas injector is substantially parallel to the substrate. The gas injector can be positioned substantially centered with at least one of the substrate and the gas aperture of the vacuum pump. The step of “injecting” can be carried out with a grazing incidence injection wherein an injection surface of the injector defines an angle above 0° and below 90° with the substrate.

According to another general aspect, there is provided an epitaxial deposition gas injector comprising: a body having a gas inlet located at a proximal end of the body and an opposed distal end and defining an annular internal gas conduit; and at least one partition wall extending in the internal gas conduit and dividing the internal gas conduit into at least one inner gas conduit section and at least one outer gas conduit section, the partition wall being configured to divide an inlet gas flux into two gas fluxes traveling along separated paths towards the distal end and back towards the proximal end.

According to still another general aspect, there is provided an epitaxial deposition gas injector comprising: a body defining an annular gas channel therein and a gas injection surface, the body having at least one gas inlet in fluid communication with the annular gas channel and at least one partition wall separating the annular gas channel into at least two gas conduit sections to provide a substantially uniform gas flux injected from the injection surface.

In an embodiment, the body is toroidally shaped.

In an embodiment, the internal gas conduit is divided into at least two inner gas conduit sections and at least two outer gas conduit sections and the gas fluxes travel separately in one of the outer gas conduit sections and the inner gas conduit sections towards the distal end and in the other one of the outer gas conduit sections and the inner gas conduit sections towards the proximal end. The internal gas conduit can be divided into two inner gas conduit sections and two outer gas conduit sections and the gas fluxes can travel separately in the outer gas conduit sections towards the distal end and in the inner gas conduit sections towards the proximal end.

In an embodiment, a first one of the gas fluxes travels in the outer gas conduit section towards the distal end and back towards the proximal end and a second one of the gas fluxes travels in the inner gas conduit section towards the distal end and back towards the proximal end. The outer gas conduit section and the inner gas conduit section can be substantially annular shaped.

In an embodiment, the gas inlet is radial to the partition wall.

In an embodiment, the gas fluxes are separated at the distal end.

In an embodiment, the epitaxial deposition gas injector further comprises elongated injection apertures provided along an injection surface of the gas injector to produce a substantially uniform injected gas flux intensity.

In an embodiment, the at least one partition wall divides the annular gas channel into at least one inner gas conduit section and at least one outer gas conduit section and wherein at least two gas fluxes travel along separated paths between a first end of the body towards a second end of the body and back to the first end.

In an embodiment, the at least one partition wall divides the annular gas channel into at least two inner gas conduit sections and at least two outer gas conduit sections and two gas fluxes travel separately in one of the outer gas conduit sections and the inner gas conduit sections towards a distal end of the body and in the other one of the outer gas conduit sections and the inner gas conduit sections towards a proximal end of the body, opposed to the distal end. The at least one partition wall can divide the annular gas channel into two inner gas conduit sections and two outer gas conduit sections and the gas fluxes can travel separately in the outer gas conduit sections towards the distal end and in the inner gas conduit sections towards the proximal end.

In an embodiment, the at least one partition wall divides the annular gas channel into an outer gas conduit section and an inner gas conduit section and a first gas flux travels in the outer gas conduit section from a proximal end of the body towards a distal end of the body, opposed to the proximal end, and back towards the proximal end and a second gas flux travels in the inner gas conduit section from one of the proximal end and the distal end towards the other one of the proximal end and the distal end and back towards the one of the proximal end and the distal end. The second gas flux can travel from the proximal end towards the distal end and back towards the proximal end in the inner gas conduit section.

According to another general aspect, there is provided a method for injecting a gas flux with a gas injector, the method comprising: injecting gas in the gas injector at a proximal end thereof; separating the gas into at least two separated gas fluxes upon entrance into the gas injector, the at least two gas fluxes traveling separately along separated gas paths from the proximal end towards an opposed distal end and back towards the proximal end; and expelling gas along the gas paths.

In an embodiment, the gas injector comprises a toroidal gas injector body.

In an embodiment, the gas is expelled substantially continuously along the gas paths.

In an embodiment, a first one of the gas fluxes travels in an inner gas conduit defined in the gas injector and a second one of the gas fluxes travels in an outer gas conduit defined in the gas injector.

In an embodiment, the fluxes travel separately towards the distal end in one of outer gas conduit sections and inner gas conduit sections, concentric with the outer gas conduit sections, and back towards the proximal end in the other one of the outer gas conduit sections and the inner gas conduit sections.

In an embodiment, the gas is injected radially in the gas injector.

According to another general aspect, there is provided a gas nozzle in combination with an epitaxial deposition gas injector, the gas nozzle comprising an elongated nozzle body having a proximal end securable to the gas injector, a distal end opposed to the proximal end and defining a gas output, at least two spaced-apart and elongated tubular walls defining therebetween an elongated gas channel extending along the nozzle body and in fluid communication with the gas injector.

According to still another general aspect, there is provided an epitaxial deposition gas injector for deposition on a substrate, the epitaxial deposition gas injector comprising: an injector body having an annular gas channel defined therein and an injection surface; and a nozzle body mounted to the injector body and having at least one elongated gas channel extending therein and a gas output oriented towards the substrate and at a distal end of the at least one elongated gas channel, the at least one elongated gas channel being in fluid communication with the annular gas channel through the injection surface.

In an embodiment, the elongated tubular walls comprise a proximal section wherein the elongated tubular walls extend substantially parallel to one another and a distal section wherein the elongated tubular walls are inclined towards a center of the nozzle body. The proximal and the distal sections of the elongated tubular walls can be contiguous. In the distal section, an outer one of two adjacent elongated tubular walls defining one of the gas channel can be less inwardly inclined than an inner one of the two adjacent elongated tubular walls.

In an embodiment, the gas injector comprises a plurality of concentric gas conduit sections and the nozzle comprises a plurality of elongated gas channels and each one of the gas conduit sections being in register with a respective one of the elongated gas channels.

In an embodiment, the elongated gas channel has an annular shape.

In an embodiment, the gas injector comprises at least one gas inlet, and a gas flux direction in the at least one gas inlet is substantially normal to a gas flux direction in the elongated gas channel of the nozzle body

In an embodiment, the elongated tubular walls of the nozzle body are concentric with one another.

In an embodiment, a length of the nozzle body is longer than a diameter of the nozzle body or the diameter of the gas injector body.

In an embodiment, the nozzle body comprises at least two concentric elongated gas channels and the injector body comprises at least one partition wall dividing the annular gas channel into at least two concentric gas conduit sections and each one of the at least two concentric gas conduit sections being in fluid communication with a respective one of the at least two elongated gas channels defined in the nozzle body.

In an embodiment, the nozzle body comprises a proximal end mounted to the gas injector body, a distal end opposed to the proximal end and defining the gas output, at least two spaced-apart and elongated tubular walls defining therebetween the at least one elongated gas channel. The elongated tubular walls can comprise a proximal section wherein the elongated tubular walls extend substantially parallel to one another and a distal section wherein the elongated tubular walls are inclined towards a center of the nozzle body.

In an embodiment, the at least one elongated gas channel has an annular shape.

According to another general aspect, there is provided a method for injecting a gas flux with a gas injector, the method comprising: injecting gas in the gas injector; separating the gas into at least two separated gas fluxes upon entrance into the gas injector, the two gas fluxes traveling separately along separated paths in the gas injector; expelling the gas along the gas paths in a nozzle having at least one elongated channel and being contiguous to the gas injector; and expelling the gas at a distal end of the nozzle towards a substrate.

In an embodiment, the method further comprises concentrating said gas prior to expelling gas towards the substrate.

In an embodiment, the gas fluxes travel in separated elongated gas channels in the nozzle.

In an embodiment, the nozzle comprises at least two concentric and elongated gas channels and the gas fluxes of the gas injector are partially combined in the at least two elongated gas channels of the nozzle and at least two gas fluxes travel separately in the at least two elongated gas channels.

In an embodiment, a gas flux direction in the gas injector is substantially normal to a gas flux direction in the at least one elongated channel of the nozzle.

According to another general aspect, there is provided a gas supply and handling system for an epitaxial deposition apparatus having a gas injector, the gas supply and handling system comprising: a housing defining a chamber and having a partition wall extending therein and separating the chamber into two chamber sections; at least one gas supply mounted in a first one of the chamber sections and having a gas conduit connected thereto and extending through the partition wall in the second one of the chamber sections, the gas conduit being in fluid communication with the gas injector of the epitaxial deposition apparatus; a heating system configured to heat ambient air contained in the chamber; and a control system operatively connected to the heating system and configured to maintain the temperature of the first one of the chamber section at a first temperature and the temperature of the second one of the chamber section at a second temperature.

In an embodiment, the second temperature is higher than the first temperature.

In an embodiment, the gas conduit extends through an aperture defined in the partition wall.

In an embodiment, the gas supply and handling system further comprises at least one blower in fluid communication with at least one of the chamber sections.

In an embodiment, the gas conduit is in controllable fluid communication with the gas injector of the epitaxial deposition apparatus.

In an embodiment, the second one of the chamber sections comprises at least two gas conduits extending therein and at least two of the gas conduits extending in the second one of the chamber sections are connected together and merge into a single gas conduit in fluid communication with the gas injector.

According to still another general aspect, there is provided a gas supply and handling system for an epitaxial deposition apparatus having a gas injector, the gas supply and handling system comprising: a housing defining a chamber; a gas supply and handling assembly including at least one gas supply and at least one gas conduit connected to the gas supply, the gas conduit being in fluid communication with the gas injector of the epitaxial deposition apparatus and extending in the chamber; and a heating system configured to heat ambient air contained in the chamber.

In an embodiment, the chamber of the housing houses at least one of a proximal section of the gas conduit being operatively connected to a respective one of the at least one gas supply and a distal section of the gas conduit. The proximal section of the gas conduit and the at least one gas supply can be surrounded by an ambient air having a first ambient air temperature, and the distal section of the gas conduit can be surrounded by an ambient air having a second ambient air temperature, wherein the second ambient air temperature can be maintained above the first ambient air temperature. The chamber of the housing can comprise at least two chamber sections separated by a partition wall and wherein the at least one gas supply is located in a first one of the chamber sections with a proximal section of the gas conduit being operatively connected to a respective one of the at least one gas supply and extending in the first one of the chamber section and a distal section of the gas conduit extending in a second one of the chamber sections and being in gas communication with the proximal section of the gas conduit. The gas conduit can extend through an aperture defined in the partition wall. The gas supply and handling system can further comprise a control system operatively connected to the heating system and configured to maintain a first ambient air temperature in the first one of the chamber sections at a first temperature and a second ambient air temperature in the second one of the chamber sections at a second temperature. It can further comprise a control system operatively connected to the heating system and configured to maintain a temperature difference between a first ambient air temperature in the first one of the chamber sections and a second ambient air temperature in the second one of the chamber sections. The second ambient air temperature can be higher than the first ambient air temperature.

In an embodiment, the gas supply and handling system further comprises at least one blower in gas communication with the chamber.

According to still another general aspect, there is provided a method for supplying gas to an epitaxial deposition apparatus, the method comprising: controlling an ambient air temperature in a first chamber housing a distal section of a gas conduit to be higher than an ambient air temperature in a second chamber housing at least one gas supply container in gas communication with a proximal section of the gas conduit, the proximal section of the gas conduit being in gas communication with the distal section of the gas conduit; and supplying gas contained in the at least one gas supply container to a gas injector of the epitaxial deposition apparatus through the proximal section and the distal section of the gas conduit.

In an embodiment, the method further comprises controlling the ambient air temperature in the second chamber.

In an embodiment, the method further comprises circulating air contained in at least one of the first chamber and the second chamber.

In an embodiment, the step of “controlling” comprises heating air contained in at least one of the first chamber and the second chamber.

In an embodiment, the step of “controlling” comprises controlling a difference of ambient air temperature between the first chamber and the second chamber.

In an embodiment, the method further comprises combining gas circulating in at least two distal sections of gas conduits extending in the first chamber into a single gas conduit in gas communication with the gas injector.

### BRIEF DESCRIPTION OF THE DRAWINGS

FIG. 1 is a perspective view of a vapor phase epitaxy (VPE) apparatus in accordance with an embodiment;

FIG. 2 is a top plan view of the vapor phase epitaxy (VPE) apparatus shown in FIG. 1;

FIG. 3 is a sectional view along section lines 3-3 of the vapor phase epitaxy (VPE) apparatus shown in FIG. 2 and wherein a housing including a substrate support is spaced-apart from a vacuum pump assembly;

FIG. 4 is a schematic view of a vapor phase epitaxy (VPE) apparatus in accordance with an embodiment;

FIG. 5 is a schematic view of a vacuum pump alignment with a normal incidence injection in accordance with an embodiment;

FIG. 6 is a schematic view of a vacuum pump alignment with a grazing incidence injection in accordance with an embodiment;

FIG. 7 is a schematic view of an apparatus including two gas injectors and two vacuum pumps and combining normal and grazing incidence injections in accordance with an embodiment;

FIG. 8 includes FIGS. 8a and 8b, FIG. 8a is a perspective view of a toroidal injector with two concentric internal conduit sections in accordance with a first embodiment and FIG. 8b is a perspective view of the toroidal injector with two concentric internal conduit sections in accordance with a second embodiment;

FIG. 9 is a perspective view of the toroidal injector shown in FIG. 8a with a base and a corresponding face plate defining an injection surface in accordance with an embodiment;

FIG. 10 is a perspective view of a nozzle mounted to a gas injector in accordance with an embodiment;

FIG. 11 is a side elevation view of the nozzle mounted on the gas injector shown in FIG. 10;

FIG. 12 is a cross-sectional view along section lines 12-12 of the nozzle mounted on the gas injector shown in FIG. 11; and

FIG. 13 is a perspective view of a housing for enclosing and heating a gas transport conduit network in accordance with an embodiment.

It will be noted that throughout the appended drawings, like features are identified by like reference numerals.

### DETAILED DESCRIPTION

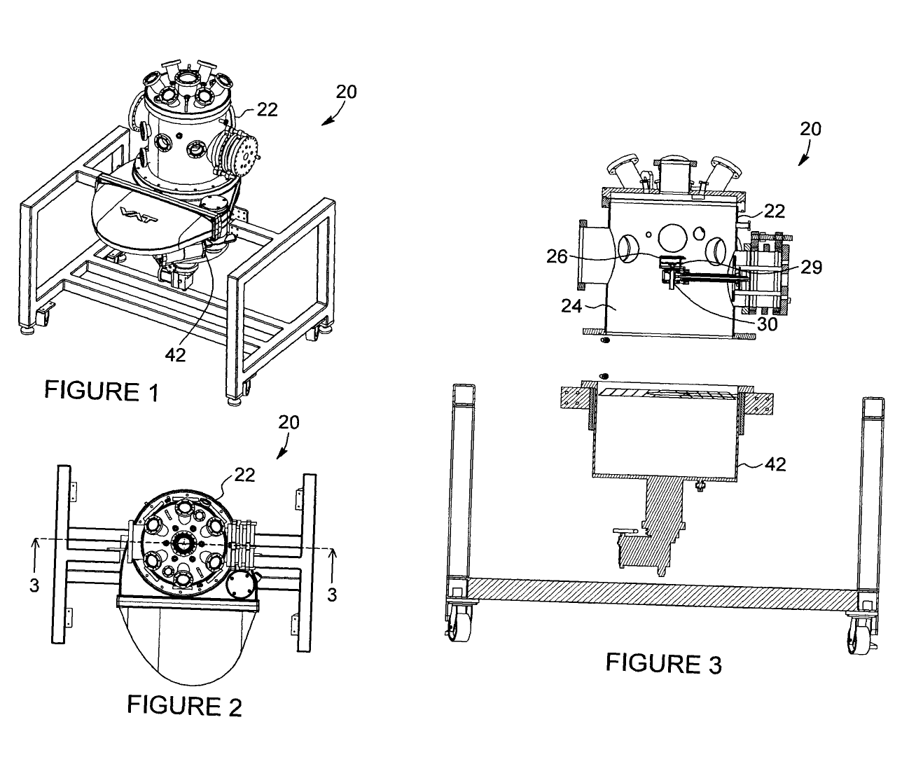

Referring now to the drawings and, more particularly, referring to FIGS. 1 to 3, a vapor phase epitaxy (VPE) apparatus 20 for chemical beam epitaxy (CBE) and related high and ultra-high vacuum based epitaxial growth techniques will be described.

The VPE apparatus 20 has a main housing 22 with a plurality of external components which will be described in more details below. The housing 22 defines a deposition vacuum chamber 24 which is configured substantially vertically.

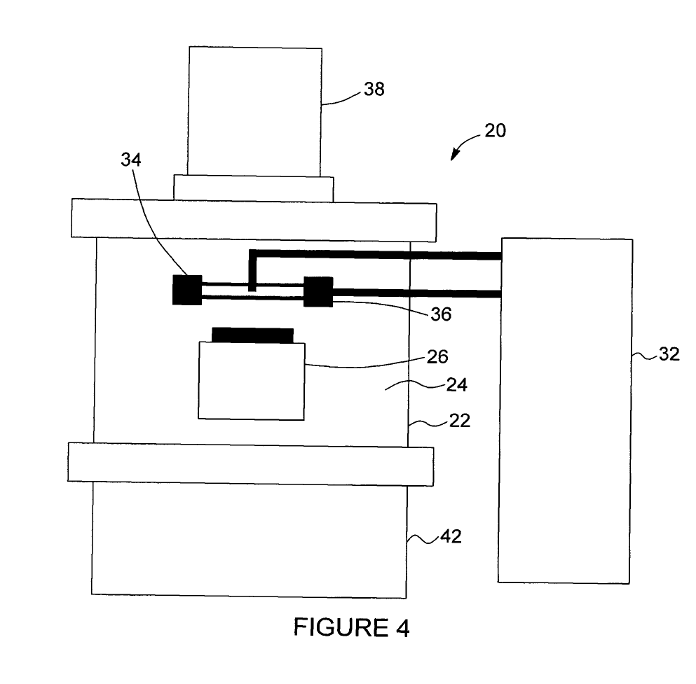

Referring now to FIGS. 3 and 4, there is shown that the deposition chamber 24 is configured to receive and support a substrate (or sample) (not shown) on which the gas molecules will be deposited. The sample is mounted on a substrate support (or platen) 26 which can be provided with a rotation system 29 to rotate the sample during the deposition process as it will be described in more details below and a heating system 30 to heat the sample during the deposition process.

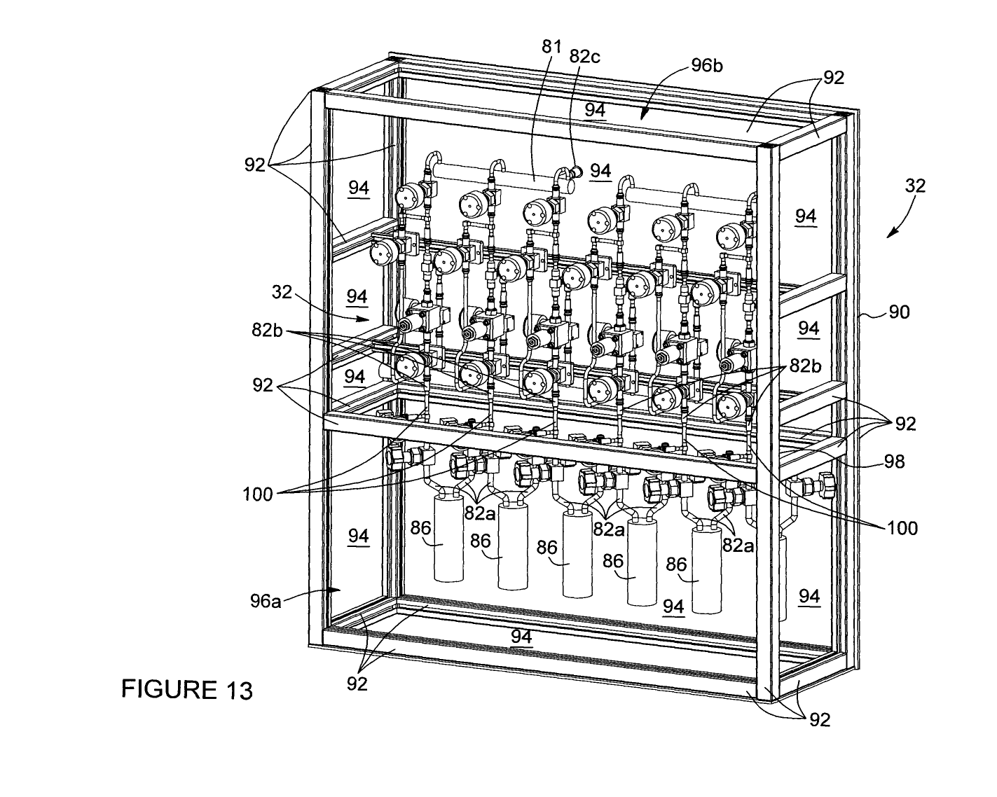

The deposition chamber 24 is linked to and, more particularly, in gas communication with a gas supply and handling system 32, which will be described in more details below in reference to FIG. 13. In the embodiment shown in FIG. 4, gases are injected in the deposition chamber 24 through two injection systems, each one including a gas injector. For instance, the first injection system 34 can be used to inject a first gas such as and without being limitative ammonia (NH₃) and the second injection system 36 can be used to inject the other reactive gases.

One skilled in the art will appreciate that the apparatus 20 can include one or a plurality of injection systems. Several gases can be injected through the same injector, as it will be described in more details below.

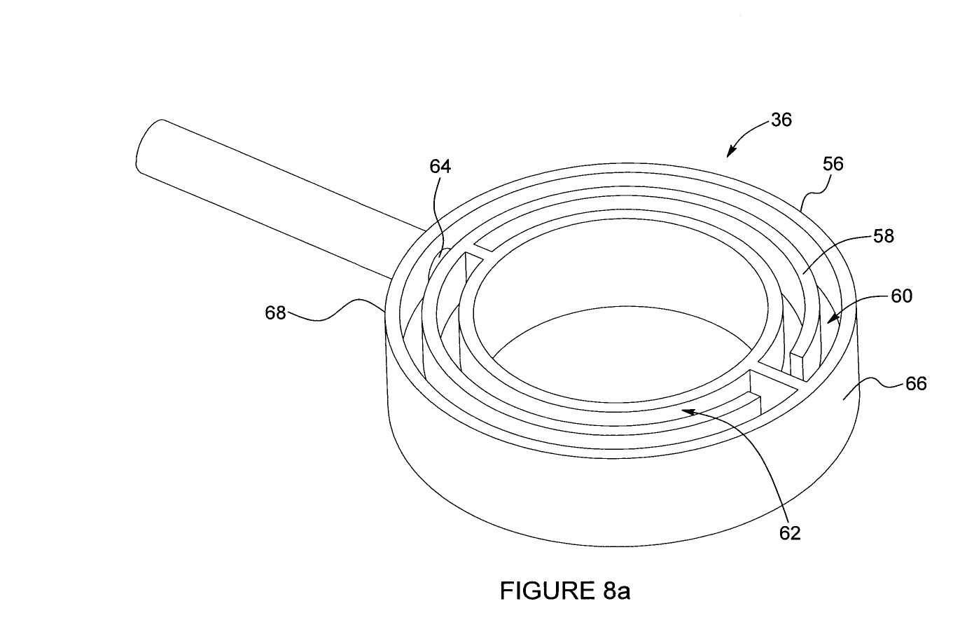

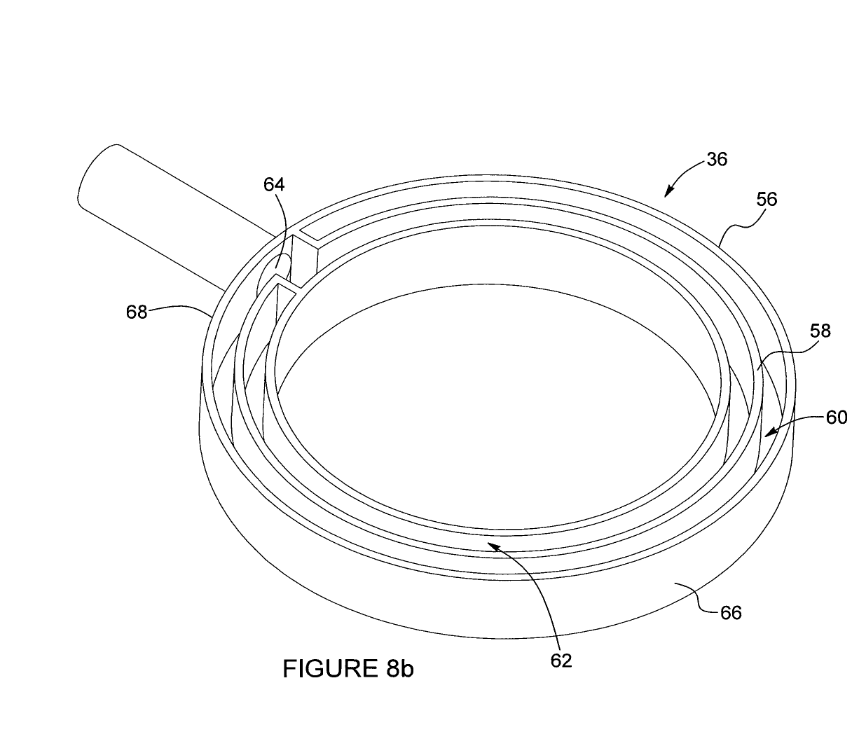

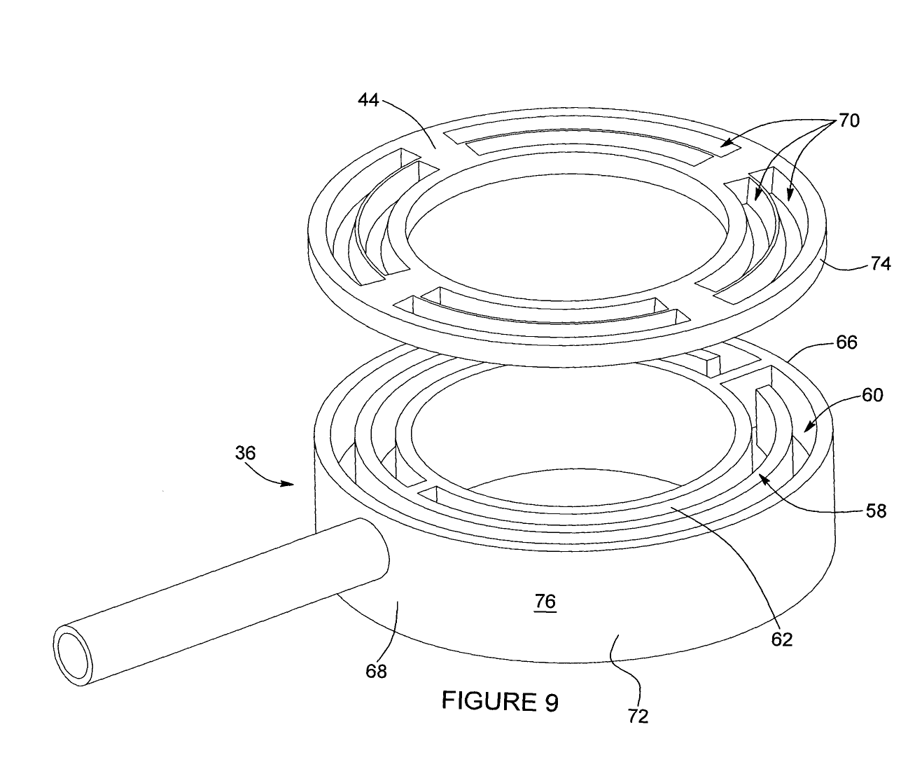

In the embodiment shown in FIG. 4, the first injection system 34 for ammonia gas ends with a showerhead injector, which includes a disk with a large number of orifices spread around its surface. In an embodiment, the first injector 34 is made of a transparent material to let light through, for instance quartz. This type of injector procures a collimated beam of molecules, directed towards the sample. The other reactive gases (OM) are sent towards the sample through another injector 36 which, in a particular embodiment, is a toroidal injector including several injection apertures defined in an injection surface facing the substrate as it will be described in more details below in reference to FIGS. 8 and 9. The different gases are supplied and controlled with the gas supply and handling system 32.

The deposition chamber 24 is also equipped with a suite of in-situ temperature monitoring instruments 38. One skilled in the art will appreciate that other parameters can also be monitored during the epitaxial deposition process.

The sample heating system is usually made of a high temperature heating element mounted in close proximity to the sample support back surface and, more particularly, to the sample back surface.

A vacuum pump 42 is mounted behind the sample and the sample support 26, in the lower portion of the apparatus 20, i.e. the substrate support 26 is mounted in the gas flux path 28 between the gas injector 34, 36 and the vacuum pump 42. The vacuum pump 42 is mounted downstream of the gas injector(s) 34, 36 with respect to the gas flux path 28. The vacuum pump 42 is in fluid communication with the deposition chamber 24 through a vacuum pump aperture 46 (or gas aperture) and removes the gaseous chemicals from the deposition chamber 24. To increase the pumping power in the deposition chamber 24, the vacuum pump aperture 46 is located in direct line with the injected gas molecules trajectory, i.e. the sample support 26 and the vacuum pump 42 are mounted along the gas flux path 28 with the sample and its sample support 26 being interposed between one or more of the injector(s) 34, 36 and the vacuum pump 42. Therefore, a fraction of the molecules that do not reach the sample surface are quickly pumped away and do not increase the background pressure in the deposition chamber 24. This configuration improves the vacuum pump efficiency. Typically, 20 to 50 wt % of the molecules that do not reach the sample surface are removed through the pump 42. This percentage is higher than with a conventional configuration wherein the aperture 46 of the vacuum pump 42 is laterally mounted with respect to the substrate, i.e. the aperture 46 is not mounted in the gas flux path 28.

In the embodiments shown in FIGS. 3 to 7, the substrate support 26 is spaced-apart from a vacuum pump assembly 42. In an embodiment (not shown), a valve such as a gate valve and a pendulum valve can be mounted in the deposition chamber 24, between the substrate support 26 is spaced-apart from a vacuum pump assembly 42.

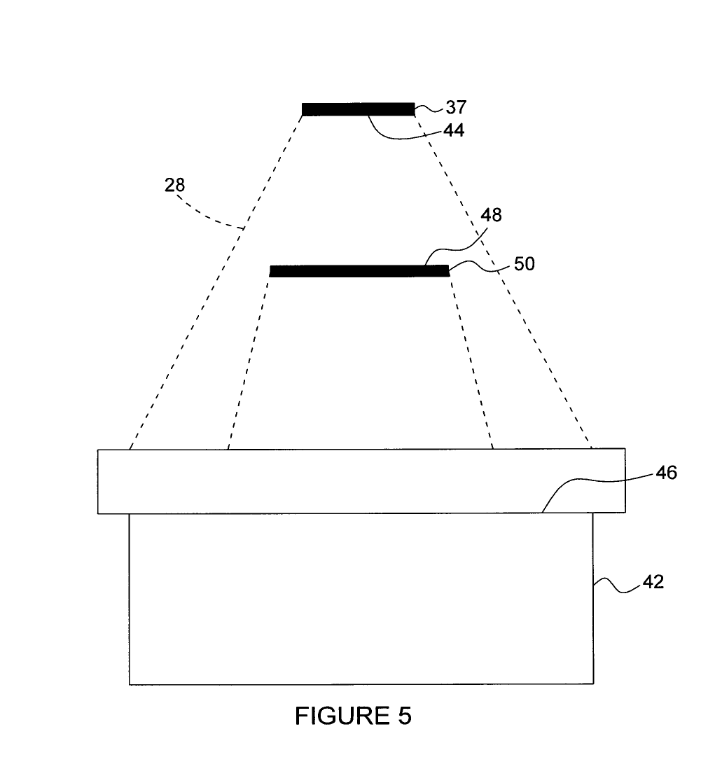

In an embodiment, the injection surface 44 of the injectors 34, 36 is aligned with the withdrawal aperture 46 of the vacuum pump 42 in a manner such that gas molecules expelled from or propelled by the injector 34, 36 and traveling in a substantially straight line are directed in the aperture 46 of the vacuum pump 42 if they do not hit the substrate 50. In the embodiment shown in FIG. 5, the gas injector 37 is positioned substantially centered and in line with the deposition surface 48 of the substrate support 50 and the gas aperture 46 of the vacuum pump 42. However, in an alternative embodiment (not shown), one skilled in the art will appreciate that the injection surface 44 of the injector 34, 36 is not compulsorily centered on the aperture 46 of the vacuum pump 42. The injected molecules that do not directly reach the substrate 50 are directed directly to the main pump and a fraction thereof is removed from the vacuum chamber, without increasing the background pressure.

The gas injection surface 44 of the gas injector 34, 36 is defined by a plurality of gas injection apertures. In the deposition chamber 24, the gas flux path 28 extends between the gas injection surface 44 and the gas aperture 46 of the vacuum pump 42, wherein the vacuum pump 42 is mounted downstream of the substrate 50 along the injected gas path. The gas aperture 46 of the vacuum pump 42 faces the injected gas path.

Thus, the gas aperture 46 of the vacuum pump 42 is configured to receive a majority of the incident gas flux 28 that is propelled in the deposition chamber 24 by one or both injectors 34, 36. In an embodiment, the gas aperture 46 of the vacuum pump 42 is theoretically configured to receive substantially the entire gas flux 28, except the molecules which deposit on the substrate 50. Thus, a fraction of the remainder of the gas flux 28 is withdrawn from the deposition chamber 24 with the vacuum pump 42 and, more particularly, through the gas aperture 46 of the vacuum pump 42.

As shown in the accompanying figures, the gas flux path 28 can be frusto-conically shaped. The aperture 46 of the vacuum pump 42 should be sufficiently large to cover a majority and substantially all the gas flux 28 which is directed towards the substrate and the vacuum pump 42 and which is not deposited on the substrate. One skilled in the art will appreciate that even if the aperture 46 of the vacuum pump 42 is sufficiently large to cover all the gas flux 28 which is directed towards the substrate and the vacuum pump 42, only a fraction of the molecules are typically removed from the deposition chamber 24.

In the apparatus 20, the injectors 34, 36 and, more particularly, their injection surfaces 44 have optical access to the sample deposition surface 48 and the vacuum pump 42.

The injectors 34, 36 are spaced apart from the substrate 50 to provide a substantially uniform gas flux 28 towards the deposition surface 48 of the substrate 50. One skilled in the art will appreciate the distance between the injectors 34, 36 and the substrate 50 can be varied.

Referring to FIG. 5, there is shown a first embodiment of a vacuum pump alignment with a normal incidence injection, i.e. the injection surface 44 of the injector 37, which can be any type of injector, is substantially parallel to the deposition surface 48 of the substrate 50. In other words, the gas molecule flux injected by the injector 37 is substantially perpendicular to the substrate 50. In the embodiment shown, the injection surface 44 of the injector 37 is also substantially parallel to the aperture 46 of the vacuum pump 42. In the embodiment shown, the gas injector 37 is positioned directly in front of the deposition surface 48 of the substrate 50. In some applications, substrate rotation can be eliminated since the resulting deposition can be substantially uniform. The vacuum pump 42 is positioned directly behind the substrate 50 and the heating unit, if any. A portion of the gas flux 28 molecules will reach the deposition surface 48 of the substrate 50 and a fraction of the remaining portion will directly enter vacuum pump aperture 46.

One skilled in the art will appreciate that the path of injected gas between the injection surface 44 of the injector 37 and the gas aperture 46 of the vacuum pump 42 is substantially frusto-conical. In the normal incidence injection, the molecules located about centrally in the gas flux 28 are propelled substantially perpendicular to the substrate 50. As mentioned above, the resulting gas flux being frusto-conically shaped, the pump aperture 46 should be large enough to accept a large proportion, substantially the entirety, of the incident gas flux 28.

One skilled in the art will appreciate that the configuration of the vacuum pump 42 can differ from the one shown. For instance, in an alternative embodiment (not shown), the aperture 46 of the pump can define an angle with at least one of the injection surface 44 of the injector 37 and the deposition surface 48 of the substrate 50.

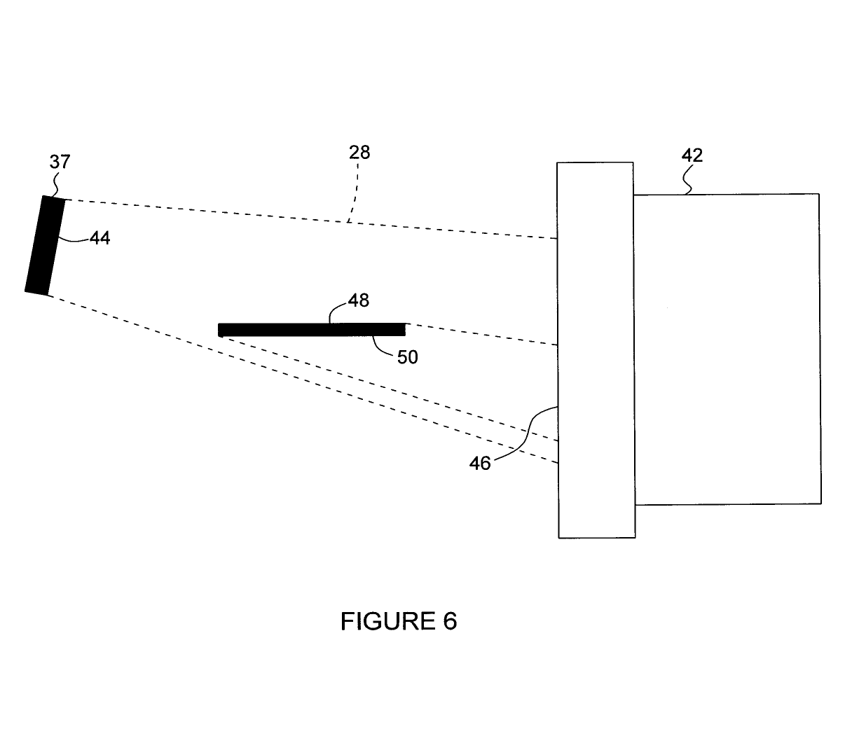

Referring to FIG. 6, there is shown a second embodiment of the vacuum pump alignment with a grazing incidence injection, i.e. the injection surface 44 of the injector 37 is angled (between greater than 0° (parallel) and below 90° (perpendicular)) relatively to the deposition surface 48 of the substrate 50. In other words, the injection surface 44 of the injector 37 and the deposition surface 48 of the substrate 50 are neither parallel nor perpendicular to one another.

In the embodiment shown, the injection surface 44 of the injector 37 is also angled (between above 0° (parallel) and below 90° (perpendicular)) relatively to the aperture 46 of the vacuum pump 42. In the embodiment shown, the deposition surface 48 of the substrate 50 is substantially perpendicular to the aperture 46 of the vacuum pump 42.

One skilled in the art will appreciate that the configuration of the vacuum pump 42 can differ from the one shown. For instance, the aperture 46 of the pump can define an angle (between above 0° (parallel) and below 90° (perpendicular)) with the deposition surface 48 of the substrate 50.

Gas injection at grazing incidence minimizes the size of the injected gas cone and relaxes the requirements for a large gas aperture 46 of the vacuum pump 42.

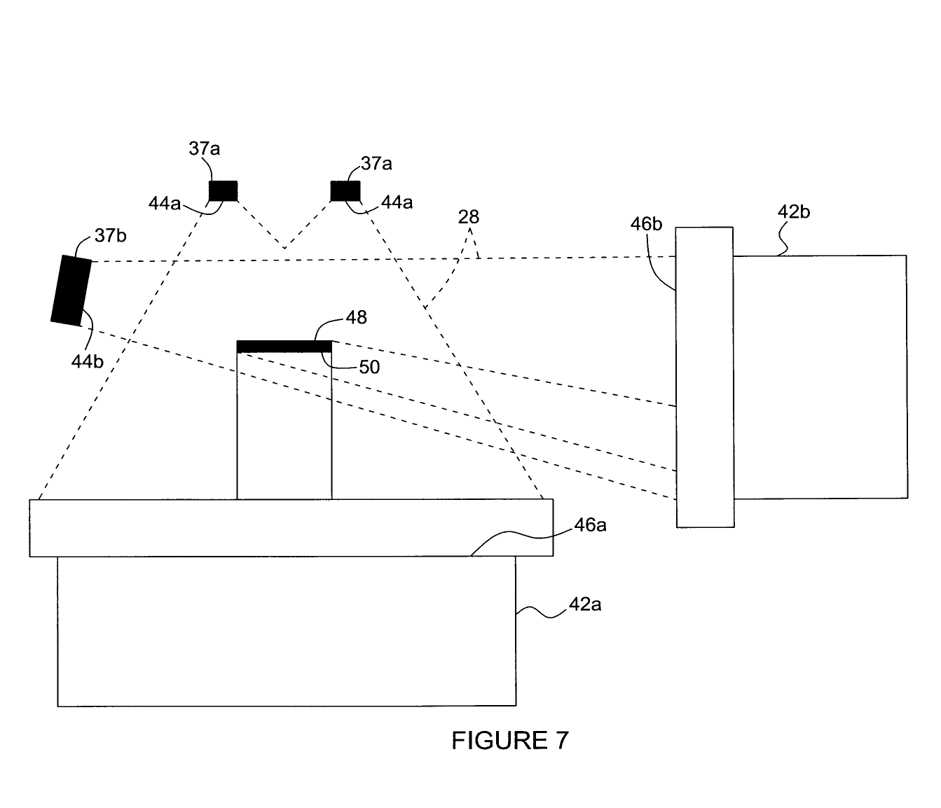

Referring to FIG. 7, there is shown a third embodiment of the apparatus 20 wherein the apparatus 20 includes two gas injectors 37a, 37b and two vacuum pumps 42a, 42b and combining normal and grazing incidence injections. Thus, two gas fluxes 28 are injected by the two gas injectors 37a, 37b, each having its own injection surface 44a, 44b, which are deposited on one substrate 50. The gas injector 37a is a toroidal gas injector wherein only a proximal end and a distal end are shown, as it will be described in more details below. A portion of the gas fluxes 28 are recovered by the vacuum pumps 42a, 42b through their apertures 46, 46b. One skilled in the art will appreciate that the apparatus 20 can include any combination and number of gas injector(s) and vacuum pump(s). Furthermore, the apparatus can be configured to provide normal incidence injection, grazing incidence injection, and combinations of both.

The combined normal and grazing incidence injections can be suitable for specific applications.

For all injection embodiments described above and illustrated, the deposition surface 48 of the substrate 50 is pointing upwards in the deposition chamber 24. The injected gas molecules arrive on the deposition surface 48 from above. However, one skilled in the art will appreciate that all these configurations can be flipped vertically for applications where it is desired to have the substrate deposition surface 48 pointing downwards to avoid particulates, for instance. Furthermore, one skilled in the art will appreciated that the substrate, the aperture of the vacuum pump and the gas injector can be oriented in any configuration including orientations wherein the substrate is vertically mounted.

One skilled in the art will appreciate that various vacuum pumps can be used. For instance and without being limitative, a turbomolecular (drag) pump, a diffusion pump, an ion pump, a Ti sublimation pump, a cryogenic pump, a rotary pump, a scroll pump, and a diaphragm pump can be used.

One skilled in the art will appreciate that various injectors can also be used. For instance and without being limitative, simple injectors with or without nozzle, multi-nozzle injectors, injectors including a low or high temperature preheating, injectors without preheating or spray-shower injectors can be used.

FIGS. 8a and 8b show two embodiments of a section of a toroidal injector 36, without a face plate 74 (shown in FIG. 9), including a circular hollow shaped body 56 defining an internal conduit and a partition wall 58 dividing the internal conduit into an outer conduit section 60 and an inner conduit section 62 in accordance with an embodiment. The outer and the inner conduit sections 60, 62 are concentric. In the embodiments shown, the injector 36 is toroidal shaped with a gas inlet 64 radially oriented with respect to the hollow shaped body 56 and the partition wall 58 at a proximal end 68 thereof.

One skilled in the art will appreciate that the gas injector can include more than one gas inlet. Furthermore, the gas inlet can be oriented to another angle than radially with the partition wall.

In the embodiment shown in FIG. 8a, upon entrance in the injector 36, gas splits in two spaced-apart fluxes in the outer conduit 60 of the injector 36 and travel along separated paths to an opposed distal end 66 of the injector 36. Then, the gas fluxes enter in the inner conduit sections 62 of the injector 36 and travel back to the first proximal end 68 still along separated paths.

In the embodiment shown in FIG. 8b, upon entrance in the injector 36, gas splits in two spaced-apart fluxes. A first one of the fluxes travels to the opposed distal end 66 and back to the first proximal end 68 in the outer conduit 60 of the injector 36. A second one of the fluxes travels to the opposed distal end 66 and back to the first proximal end 68 in the inner conduit 60 of the injector 36. Thus, the incoming flux is separated into two fluxes which travel separately to an opposed distal end 66 of the injector 36 and back to the first proximal end 68.

One skilled in the art will appreciate that alternative embodiments can be foreseen. For instance and without being limitative, in an alternative embodiment, upon entrance in the injector, gas can split in two spaced-apart fluxes in the inner conduit 60 of the injector 36 and travel along separated paths to an opposed distal end 66 of the injector 36. Then, the gas fluxes enter in the outer conduit sections 62 of the injector 36 and travel back to the first proximal end 68 still along separated paths.

For both embodiments (FIGS. 8a and 8b), along the gas flux paths in the gas conduit sections, the gas pressure lowers. In other words, when the gas enters the injector 36, the gas pressure is relatively high. When the gas fluxes reach the distal end 66, the gas pressure is relatively medium. Finally, when the gas fluxes return to the proximal end 68, the gas pressure is relatively low in comparison with the pressure at entrance. The toroidal injector 36 with double internal conduits 60, 62 provides a substantially uniform gas flux injected from the injection surface 44 since relatively high pressure zones are adjacent to relatively relatively low pressure zones while a relatively middle pressure zone is adjacent to another relatively middle pressure zone. This zone combination provides a substantially uniform gas flux for the entire injection surface 44 of the injector 36. Thus, the partition wall 58 divides the annular gas channel defined in the body 56 of the gas injector 36 in a manner such that the injected gas flux in the deposition chamber 24 is substantially uniform over the injection surface 44 of the gas injector 36. Thus, the inner and outer conduit sections are provided in a manner such that the injection surface 44 of the gas injector 36 injects a substantially uniform or equal gas flux in the deposition chamber 24.

In an alternative embodiment, the injector 36 can be donut shaped, toroid shaped, torus shaped, quoit shaped or disk shaped with a plurality of internal conduits 60, 62 defined therein to equalize the gas flux injected in the deposition chamber.

In an alternative embodiment, one skilled in the art will appreciate that the toroidal injector 36 can include more than two internal conduit sections 60, 62. In an embodiment, the toroidal injector 36 includes an even number of concentric internal conduit sections. In an embodiment, the cross-sectional area of each one of the internal conduit sections, i.e. its diameter, can be the same or can be varied to equalize the injected gas flux.

Injection apertures 70 are provided along both internal conduit sections 60, 62 of the toroidal injector 36 defined in the injection surface of the gas injector. Gas is expelled from the injector 36 through the injection apertures 70 and towards the substrate 50. In an embodiment, the injection apertures 70 are conically shaped and provided successively along both internal conduits 60, 62. In another embodiment, the injection apertures 70 are elongated slot shaped as shown in FIG. 9 with inclined inner walls, i.e. the aperture surface close to the inner conduits is smaller than the aperture surface at the injection surface 44 (or outer surface) of the injector 36. One skilled in the art will appreciate that the shape, number and configuration of the injection apertures can vary from the one described above in reference to the drawings. For instance and without being limitative, the apertures can be of any shape such as conical, cylindrical, rectangular and the like.

In FIG. 9, the injector 36 of FIG. 8a includes two main components: a base 72 and a face plate (or cover) 74. The base 72 has peripheral walls 76 that define an annular gas channel and partition walls 58 that divide the annular gas channel into the internal conduits 60, 62 of the injector 36. The face plate 74 is superposable and securable over the base 72 to partially close the internal conduits 60, 62 and control gas release. The face plate 74 defines the injection surface 44 of the injector 36. In the embodiment, the injection apertures 70 defined in the face plate 74 are quarter annular shaped. As mentioned above, a person skilled in the art will appreciate that the shape of the apertures can vary from the embodiment shown in FIG. 9, as mentioned above.

The toroidal injector 36 provides a substantially uniform gas flux intensity on a circular surface, without requiring rotation of the substrate 50. Furthermore, the toroidal injector 36 ensures that a significant portion of the injected gas reaches directly the deposition surface, thereby improving the process efficiency.

One skilled in the art will appreciate that several toroidal injectors can be mounted in a concentric relationship.

In an alternative embodiment, the injector can have a circular body with substantially annular shaped internal channel defined therein and divided into at least two gas conduit sections.

In an alternative embodiment (not shown), the gas injector can have more than one gas inlet. For instance, the gas injector can include two gas inlets mounted at opposed ends of the gas injector body, i.e. one gas inlet is provided at a proximal end of the gas injector body and the other gas inlet is provided at a distal end of the gas injector body. The gas injector body can be similar to the configuration shown in either one of the embodiments shown in FIGS. 8a and 8b. In a configuration similar to the embodiment shown in FIG. 8a, gas flowing from a first one of the gas inlets can travel from a first end (close to its respective gas inlet) towards a second end, opposed to the first end, and back towards the first end, opposed to the first end, in adjacent gas conduit sections. Gas flowing from a second one of the gas inlets can travel from a first end (close to its respective gas inlet) towards a second end, opposed to the first end, and back towards the first end in adjacent gas conduit sections. In a configuration similar to the embodiment shown in FIG. 8b, gas flowing from the gas inlets can travel in substantially annular shaped gas conduits, concentric with one another. Thus gas flowing from a first one of the gas inlet flows from a first end (close to its respective gas inlet) towards a second end, opposed to the first end, and back towards the first end in an inner gas conduit. Gas flowing from a second one of the gas inlets can travel from a first end (close to its respective gas inlet) towards a second end, opposed to the first end, and back towards the first end in an outer gas conduit, adjacent and concentric with the inner gas conduit.

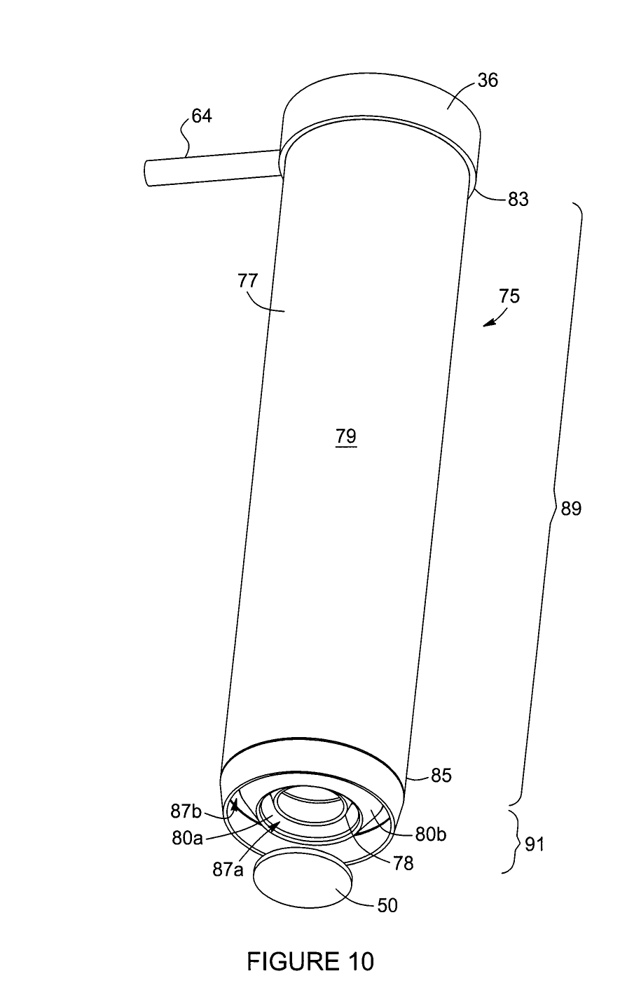

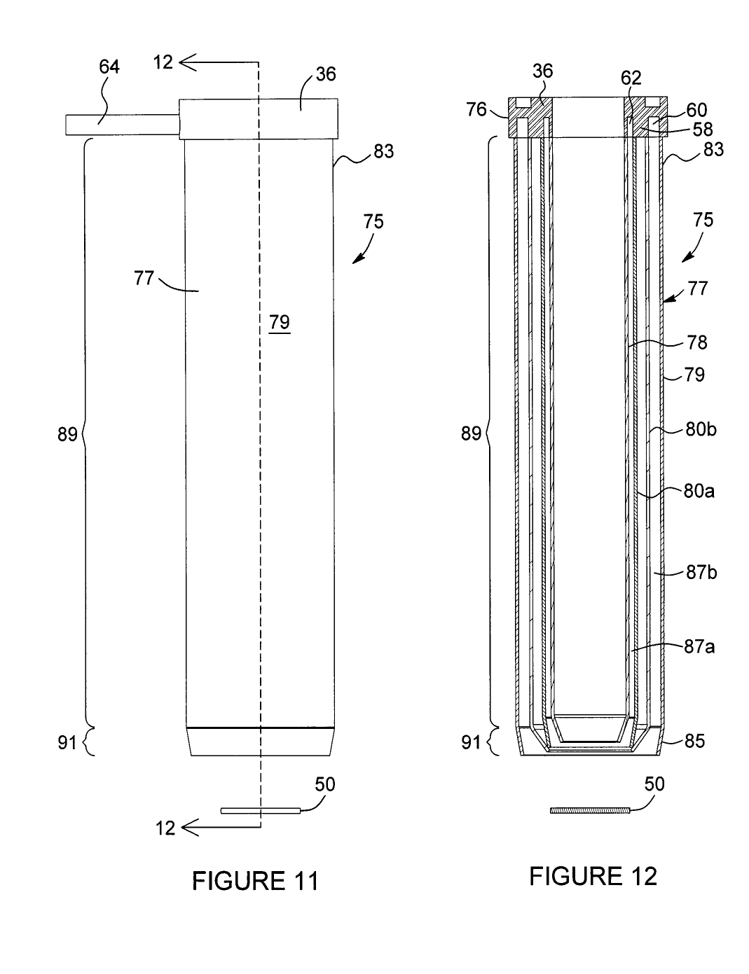

Referring now to FIGS. 10 to 12, there is shown an elongated nozzle 75 mounted to a gas injector, which can be a conventional gas injector or a toroidal gas injector such as the one shown in FIGS. 8a, 8b, and 9. In the embodiment shown in FIGS. 10 to 12, the gas injector is a toroidal gas injector 36.

The nozzle 75 has an elongated body 77 defined by a plurality of substantially concentric elongated tubular walls 78, 79, 80a, 80b. More particularly, in the embodiment shown, the nozzle 75 has a tubular and elongated outer wall 79 which extends from a proximal end 83 mounted to the gas injector 36 to an opposed distal end 85, which corresponds to the gas output of the nozzle 75. It also includes a tubular and elongated inner wall 78 which also extends from the proximal end 83 to the opposed distal end 85. The inner wall 78 is spaced apart and concentric with the outer wall 79. In the embodiment shown, the nozzle 75 also includes two elongated and internal partition walls 80a, 80b, each one of the partition walls 80a, 80b being associated with a respective one of the inner wall 78 and the outer wall 79 and defining therewith an elongated and annular gas channel 87a, 87b. Thus, the nozzle 75 has an elongated and annular inner gas channel 87a which is defined between the inner wall 78 and the innermost one 80a of the elongated and internal partition walls 80a, 80b. The nozzle 75 also has an elongated and annular outer gas channel 87b which is defined between the outer wall 79 and the outermost one 80b of the elongated and internal partition walls 80a, 80b.

In the embodiment shown, the two elongated and internal partition walls 80a, 80b are spaced-apart from one another and concentric with one another and with the inner and outer walls 78, 79. One skilled in the art will appreciate that in an alternative embodiment, the nozzle 75 can include only one partition wall and the partition wall defines the inner gas channel and the outer gas channel with a respective one of the inner wall 78 and the outer wall 79.

In the embodiment shown, the inner gas channel 87a of the nozzle 75 is mounted in register with the inner conduit 62 (or conduit sections) of the gas injector 36. Thus gas flowing in the inner conduit 62 (or conduit sections) of the gas injector 36 then flows in the inner gas channel 87a of the nozzle 75 towards the gas output. The inner gas channel 87a of the nozzle 75 and the gas injector 36 are thus in fluid communication. Similarly, the outer gas channel 87b of the nozzle 75 and the outer conduit section 60 of the gas injector 36 are in fluid communication and mounted in register. Gas flowing in the outer conduit section 60 (or conduit sections) of the gas injector 36 then flows in the outer gas channel 87b of the nozzle 75 towards the gas output.

If the nozzle 75 is operatively connected to a gas injector similar to the one shown in FIG. 8a, the gas expelled from the injector while flowing in the outer gas conduit sections 60 flows in the outer gas channel 87b while the gas expelled from the injector while flowing in the inner gas conduit sections 62 flows in the inner gas channel 87a.

The central section of the gas injector 36 is in register with the central elongated channel of the nozzle 75 and no gas flows therein.

One skilled in the art will appreciate that several alternative embodiments can be foreseen. For instance and without being limitative, the nozzle 75 can be partition wall free and thus include only one elongated gas channel defined between the inner and the outer elongated walls 78, 79. Moreover, the nozzle 75 can include any number of partition walls and thus any number of gas channels defined therebetween. Thus, the nozzle 75 can include two or more substantially concentric and elongated gas channels.

The elongated gas channels can be contiguous or separated by another channel in which no gas flows.

In the embodiment shown, the nozzle 75 comprises an elongated channel extending between the inner and outer gas channels 87a, 87b and defined by the adjacent inner and outer partition walls 80a, 80b. In the embodiment shown, no gas flows in this intermediate channel. However, in alternative embodiments (not shown), the inner and outer gas channels 87a, 87b can be contiguous to one another with no elongated channel extending therebetween or gas can flow in the intermediate elongated channel. One skilled in the art will appreciate that the configuration of the gas injector 36 will be adjusted accordingly.

Similarly, in the embodiment shown, no gas flows in the central channel defined inwardly of the inner wall 78. However, in alternative embodiments (not shown), the central channel can be filled or gas can flow therein. One skilled in the art will appreciate that the configuration of the gas injector 36 will be adjusted accordingly.

In the embodiment shown, the walls 78, 79, 80a, 80b are elongated tubular members with a circular cross-section. In alternative embodiments, the 78, 79, 80a, 80b can be tubular members having a non-circular cross-section. For instance and without being limitative, their cross-sections can be square, rectangular, triangular, and the like.

The gas flow direction in the inner and outer gas channels 87a, 87b of the nozzle 75 is oriented normal to the gas flow direction in the inner and outer gas conduits 62, 60 of the gas injector 36. Thus, gas flowing in the gas conduits 62, 60 of the gas injector 36 flows in a substantially perpendicular direction in the downstream nozzle 75. The gas channels 87a, 87b of the nozzle 75 are also oriented substantially normal to the injector gas inlet 64. Similarly, gas flow direction in the gas inlet 64 is substantially normal (or perpendicular) to the gas flow direction in the gas channels 87a, 87b of the nozzle 75.

In the embodiment shown, the nozzle 75 is mounted to the original injection surface 44 of the injector body 56. It replaces the face plate 74 shown in FIG. 9. However, in an alternative embodiment (not shown), the nozzle 75 can be mounted to the gas injector 36 including the face plate 74.

The inner, outer, and partition walls 78, 79, 80a, 80b can be divided into two sections: a first and substantially straight section 89 (or proximal section) extending from the proximal end 83 towards the distal end 85 and a second and inwardly inclined section 91 (or distal section) extending from the distal end 85. The first and second sections 89, 91 are contiguous. In the first section 89, the inner, outer, and partition walls 78, 79, 80a, 80b extend substantially parallel to one another. In the second section 91, the inner, outer, and partition walls 78, 79, 80a, 80b are inclined towards the center of the nozzle 75. The second section 91 of the walls 78, 79, 80a, 80b are deflectors which direct the gas flow towards the substrate 50 which is mounted downstream of the nozzle 75. The second section 91 of the walls 78, 79, 80a, 80b further concentrates the gas flow towards the substrate 50.

In the embodiment shown, the second section 91 of the innermost wall defining one of the gas channels 87a, 87b is more inclined inwardly than the second section 91 of the outermost wall defining the respective one of the gas channels 87a, 87b. More particularly, the second section 91 of the outermost partition wall 87b is more inclined inwardly than the second section 91 of the outer wall 79. Similarly, the second section 91 of the inner wall 78 is more inclined inwardly than the second section 91 of the innermost partition wall 87a.

For instance, the angle defined between the walls of the first section 89 and the walls of the second section 91 can range between 25 and 50 degrees and, in a particular embodiment, the angle ranges between 30 and 40 degrees.

The length of walls 78, 79, 80a, 80b can be similar or different. For instance, in the embodiment shown, the outer walls are longer than the inner walls (including the partition walls). More particularly, the outer wall 79 is the longest wall while the outer partition wall 80b is longer than the inner partition wall 80a and the inner wall 78 but shorter than the outer wall 79. Similarly, the inner partition wall 80a is longer than the inner wall 78 but shorter than the outer wall 79 and the outer partition wall 80b. Finally, the inner wall 78 is the shortest wall.

Furthermore, the length of each section 89, 91 for each one of the walls 78, 79, 80a, 80b can vary. In the embodiment shown, the walls 78, 79, 80a, 80b are divided by pairs with the outer wall 79 and the outer partition wall 80b forming a first one of the pairs and the inner wall 78 and the inner partition wall 80a forming a second one of the pairs. The walls 79, 80b of the first one of the pairs have a longer first section than the walls 78, 80a of the second one of the pairs. Thus, the inner gas channel 87a is shorter than the outer gas channel 87b.

The gas output of the nozzle 75 is closer to the substrate 50 than the gas injector 36. Thus, the gas flux expelled by the gas injector 36 having an elongated nozzle 75 mounted thereto is more directed and concentrated towards the substrate 50 and enhances the deposition.

The length of the inner, outer, and partition walls 78, 79, 80a, 80b and the corresponding elongated gas channels 87a, 87b of the nozzle 75 are longer than its diameter, which substantially corresponds to the diameter of the corresponding gas injector 36. Thus, the nozzle 75 directs and concentrates the injected gas flux towards the substrate 50.

In the embodiment shown, the nozzle 75 and the gas injector 36 are two components assembled together. However, one skilled in the art will appreciate that in an alternative embodiment, the nozzle 75 and the gas injector 36 can be a single component mounted in the deposition chamber 24.

For high performance deposition, the apparatus 50 must be able to supply very stable and predictable amounts of gas to the sample surface 48. It should be able to switch the gas flux on and off within a fraction of a second. This level of control can be achieved through the use of a pressure control scheme 82, where the gas flux is obtained by maintaining a constant pressure inside a control volume that is linked to the vacuum chamber 24 by an orifice that acts as a calibrated leak.

Since several different types of reactive process gases are necessary for the operation of the apparatus, it must include several lines with pressure control cells. One problem that can occur during the operation is condensation of the process gases on the line walls and the formation of droplets. Gas condensation must be avoided since it causes harder control of the reactive gas flux. To prevent gas condensation, all metallic surfaces in contact with the reactive gases should be maintained at a temperature that is several tens of degrees Celsius higher that the gas temperature.

In the apparatus 20, this is obtained by enclosing all gas conduit lines 82 in an evacuated and heated cabinet or housing 84 as shown in FIG. 13. This ensures a substantially uniform temperature throughout the gas handling system 32, but it also facilitates the maintenance by avoiding use of heating tapes applied to the gas conduits, which are often used in such systems. The air contained in the housing 84 is evacuated and directed towards a chimney on a regular basis or continuously. Thus, in case of a gas leak, gases contained in the housing 84 are directed in the chimney instead of the ambient air of the laboratory or the plant.

Reactive gases flow from gas supplies 86, typically pressurized gas bottles, where pressure ranges between 0.001 and 20 atmosphere (atm) to an injection zone where pressure is in the order of 0.00001 atm. One skilled in the art will appreciate that gas supplies can include, without being limitative, compressed or pressurized gas, liquids or solids. If the gas supplies contain a liquid or a solid, the latter are supplied in vapor phase to the gas conduits.

In an embodiment (not shown), each one of the gas supplies 86 is connected to an individual gas transport conduit 82 which allows gas/fluid communication between their respective gas supply 86 and the injector(s) (not shown). In other words, the individual gas transport conduits 82 are operatively connected to their respective gas supply 86 and their respective injector(s).

Valves and other sensors including pressure gauge can be operatively connected to the transport conduits 82 and are part of the gas transport components.

In an embodiment (not shown), each gas transport conduit 82 is operatively connected to an individual injector which is mounted in and releases gases in a vacuum deposition chamber. Therefore, the number of injectors is equal to the number of gas supplies 86.

In an alternative embodiment such as the one shown in FIG. 13, to reduce the number of injectors, a gas supply and handling system 32 can have a single common downstream conduit with a high hydraulic conductivity connecting together a plurality of upstream gas conduits, each one of the upstream gas conduits being operatively connected to a respective gas supply, and wherein the single common downstream conduit is operatively connected to a common gas injector.

Gas transport is carried out in a rarefied state, i.e. the gas molecules almost never interact together and collisions with the conduit walls in which they circulate are rare. For instance, in the rarified state, the gas pressure is below about 0.01 Torr. Therefore, several gases, which require similar injection conditions, such as and without being limitative similar pressures and flow rates, can share the same conduit 82 and the same injector.

To substantially prevent condensation on the gas transport conduits 82, gas temperature in the gas transport conduits 82 and in the injector must slightly exceed the gas temperature in the gas supply bottles 86, as mentioned above.

Referring now to FIG. 13, there is shown that the gas supply and handling system 32 is enclosed in a housing 90 having a plurality of horizontal and vertical frame members 92, which can be made of aluminum, and panels 94 extending between the frame members 92 for defining a chamber 96 containing the gas supplies 86 and the gas transport components. In the embodiment shown, the gas supplies 86 include pressurized gas supply containers and the gas transport components include, amongst others, gas conduits 82, valves, pressure gauges, and other sensors.

The chamber 96 is vertically divided into two sections 96a, 96b separated by a horizontally extending partition wall 98 and, more particularly, a plexiglass plate. The horizontally extending plexiglass plate 98 has a plurality of holes or apertures 100 defined therein in which the gas conduits 82 extend. The lower chamber section 96a includes a plurality of gas supply bottles 86 and relatively short sections of gas conduits 82, which are referred to as proximal sections of upstream gas conduits 82 that are operatively connected to a respective one of the gas supply bottles or containers 86.

The upper chamber section 96b includes the remaining sections of the upstream gas conduits 82 and other gas transport components such as the valves 88 and the manometers. The remaining sections of the upstream gas conduits 82 are referred to as the distal section of the upstream gas conduits 82 which are in gas communication with the proximal sections housed in the lower chamber section 96a. Thus, the upstream gas conduits 82 extend continuously between the proximal and the distal sections.

In a non-limitative embodiment, the ambient air in the lower chamber section 96a is maintained at a temperature close to the ambient temperature. The upper chamber section 96b has an ambient temperature higher than the lower chamber section 96a. In an embodiment, the temperature in the upper chamber section 96b is a few tens of degrees Celsius above the temperature in the lower chamber section 96a. For instance and without being limitative, the ambient air temperature in the upper chamber section 96b is about 20 degrees Celsius above the ambient air temperature in the lower chamber section 96a. The plexiglass partition wall 98 and the panels 94 ensure relative thermal insulation between both chambers and between the ambient air external to the housing 90. One skilled in the art would appreciate that the panels 88, 96 and the frame members 92 can be made of other suitable materials and that the shape and configuration of the housing 90 and the gas transport components can differ from the embodiment shown. For instance, materials with enhanced insulating properties can be used for the panels 94 and the partition wall 98.

In the embodiment shown, heated air is introduced in the upper chamber section 96b through an aperture defined in one of the panels 88. Temperature sensor(s) can be mounted in the chamber 96 to control the heating system and maintain a substantially constant temperature.

A ventilation system can also be operatively connected to the chamber 96 to evacuate the gases contained therein, if needed. It can further include a control system configured to control the temperature inside at least one of the chamber sections. For instance, the control system can be operatively connected to the heating system and, optionally to the ventilation system. It can be configured to maintain the ambient air temperature in at least one of the chamber sections 96a, 96b at a predetermined temperature set-point or to maintain the ambient air temperature difference between both chamber sections 96a, 96b at a predetermined set-point. Thus, appropriate temperature sensors must be provided in the housing 90 to measure the ambient air temperature in at least one of the chamber sections 96a, 96b.

In a non-limitative embodiment, the ambient air temperature is measured in both chamber sections 96a, 96b and each one of the chamber is maintained at its own temperature set-point. In a non-limitative and alternative embodiment, the ambient air temperature is measured in both chamber sections 96a, 96b and the difference of temperatures is controlled. For instance, the heating system can be operatively connected to only one of the chamber sections 96a, 96b and the ambient air temperature in this chamber section is adjusted in a manner such that the difference of temperatures between both chamber sections 96a, 96b is close to the predetermined set-point.

One skilled in the art will appreciate that several embodiments can be foreseen for controlling the relative ambient air temperature in chamber sections 96a, 96b.

The housing 90 can further include one or several fan(s) or any other appropriate blower(s) than ensure a substantially uniform ambient air temperature in the chamber sections 96a, 96b. Each one of the chamber sections 96a, 96b can include its own blower or one blower can be operatively connected to both chamber sections 96a, 96b. The fan(s) can be operatively connected to the control system.

As mentioned above, several gases, which require similar injection conditions, can share the same conduit 82 and the same gas injector. As shown in FIG. 13, several distal upstream gas conduits 82b are connected together and in fluid communication in the upper chamber section 96b. More particularly, in the embodiment shown, gases flowing from three gas supplies 86 and into a plurality of proximal and distal upstream gas conduits 82a, 82b combine in a manifold 81 and flows outwardly of the housing 90 into a single upstream gas conduit 82c which is in fluid communication with a gas injector of the epitaxial deposition apparatus. Thus the number of gas conduits 82 can be reduced in the chamber section 96b housing the distal gas conduits 82b.

In the embodiment shown, the housing includes two chamber sections with the gas supply containers 86 and the proximal sections of the gas conduits 82 housed in the lower chamber section and the distal sections of the gas conduits 82 and the other gas transport components housed in the upper chamber section. However, in an alternative and non-limitative embodiment (not shown), one skilled in the art will appreciate that the lower chamber section can house the distal sections of the gas conduits 82 and the other gas transport components while the upper chamber section can house the gas supply containers 86 and the proximal sections of the gas conduits 82. Furthermore, in another alternative and non-limitative embodiment (not shown), the two chamber sections can be configured side-by-side or spaced-apart from one another. Furthermore, in still another alternative and non-limitative embodiment (not shown), the gas supply and handling system 32 can include more than two chamber sections.

Furthermore, in still another alternative and non-limitative embodiment (not shown), the gas supply and handling system 32 can include only one chamber housing either the gas supply containers 86 and the proximal sections of the gas conduits 82 or the distal sections of the gas conduits 82 and the other gas transport components. If the single chamber houses the gas supply containers 86 and the proximal sections of the gas conduits 82, the ambient temperature in the chamber is controlled to be below the ambient temperature surrounding the distal sections of the gas conduits 82 and the other gas transport components. In the alternative, if the single chamber houses the distal sections of the gas conduits 82 and the other gas transport components, the ambient temperature in the chamber is controlled to be above the ambient temperature surrounding the gas supply containers 86 and the proximal sections of the gas conduits 82.

In a non-limitative embodiment, the deposition chamber 24 is designed to contain a 50 to 300 mm diameter platen 26. Several apparatuses 20 can be mounted in a cluster with a plurality of chambers 24. It is appreciated that when the apparatuses 20 are configured in clusters, they can share several components of the apparatuses, for instance the gas supply and handling system. This modular approach allows for progressive upgrades, along with the increased demand. Furthermore, multiple chambers reduce downtime because single chambers can be taken down for maintenance and repairs, while other chambers are operating.

The semiconductor films manufactured with the above-described apparatus can be used in telecommunication technologies (electronics and photonics), liquid crystal display backlighting for cell phones and flat screens, high power LED technologies for lighting applications, blue lasers for high density data storage (Blue ray and others), high efficiency, multi-junction, concentrated solar cells, and high energy density electronics for electrical and hybrid motors, for instance and without being limitative.

Several alternative embodiments and examples have been described and illustrated herein. The embodiments of the invention described above are intended to be exemplary only. A person of ordinary skill in the art would appreciate the features of the individual embodiments, and the possible combinations and variations of the components. A person of ordinary skill in the art would further appreciate that any of the embodiments could be provided in any combination with the other embodiments disclosed herein. It is understood that the invention may be embodied in other specific forms without departing from the spirit or central characteristics thereof. The present examples and embodiments, therefore, are to be considered in all respects as illustrative and not restrictive, and the invention is not to be limited to the details given herein. Accordingly, while the specific embodiments have been illustrated and described, numerous modifications come to mind without significantly departing from the spirit of the invention. The scope of the invention is therefore intended to be limited solely by the scope of the appended claims.

1-26. (canceled)

27. An epitaxial deposition gas injector comprising:
a body having a gas inlet located at a proximal end of the body and an opposed distal end and defining an annular internal gas conduit; and
at least one partition wall extending in the internal gas conduit and dividing the internal gas conduit into at least one inner gas conduit section and at least one outer gas conduit section, the partition wall being configured to divide an inlet gas flux into two gas fluxes traveling along separated paths towards the distal end and back towards the proximal end.

28. The epitaxial deposition gas injector as claimed in claim 27, wherein said body is toroidally shaped.

29. The epitaxial deposition gas injector as claimed in claim 27, wherein the internal gas conduit is divided into at least two inner gas conduit sections and at least two outer gas conduit sections and the gas fluxes travel separately in one of the outer gas conduit sections and the inner gas conduit sections towards the distal end and in the other one of the outer gas conduit sections and the inner gas conduit sections towards the proximal end.

30. The epitaxial deposition gas injector as claimed in claim 29, wherein the internal gas conduit is divided into two inner gas conduit sections and two outer gas conduit sections and the gas fluxes travel separately in the outer gas conduit sections towards the distal end and in the inner gas conduit sections towards the proximal end.

31. The epitaxial deposition gas injector as claimed in claim 27, wherein a first one of the gas fluxes travels in the outer gas conduit section towards the distal end and back towards the proximal end and a second one of the gas fluxes travels in the inner gas conduit section towards the distal end and back towards the proximal end.

32. The epitaxial deposition gas injector as claimed in claim 31, wherein the outer gas conduit section and the inner gas conduit section are substantially annular shaped.

33. The epitaxial deposition gas injector as claimed in claim 27, wherein the gas inlet is radial to the partition wall.

34. The epitaxial deposition gas injector as claimed in claim 27, wherein the gas fluxes are separated at the distal end.

35. The epitaxial deposition gas injector as claimed in claim 27, further comprising elongated injection apertures provided along an injection surface of the gas injector to produce a substantially uniform injected gas flux intensity.

36. An epitaxial deposition gas injector comprising:
a body defining an annular gas channel therein and a gas injection surface, the body having at least one gas inlet in fluid communication with the annular gas channel and at least one partition wall separating the annular gas channel into at least two gas conduit sections to provide a substantially uniform gas flux injected from the injection surface.

37. The epitaxial deposition gas injector as claimed in claim 36, wherein the at least one partition wall divides the annular gas channel into at least one inner gas conduit section and at least one outer gas conduit section and wherein at least two gas fluxes travel along separated paths between a first end of the body towards a second end of the body and back to the first end.

38. The epitaxial deposition gas injector as claimed in claim 36, wherein said body is toroidally shaped.

39. The epitaxial deposition gas injector as claimed in claim 36, wherein the at least one partition wall divides the annular gas channel into at least two inner gas conduit sections and at least two outer gas conduit sections and two gas fluxes travel separately in one of the outer gas conduit sections and the inner gas conduit sections towards a distal end of the body and in the other one of the outer gas conduit sections and the inner gas conduit sections towards a proximal end of the body, opposed to the distal end.

40. The epitaxial deposition gas injector as claimed in claim 39, wherein the at least one partition wall divides the annular gas channel into two inner gas conduit sections and two outer gas conduit sections and the gas fluxes travel separately in the outer gas conduit sections towards the distal end and in the inner gas conduit sections towards the proximal end.

41. The epitaxial deposition gas injector as claimed in claim 36, wherein the at least one partition wall divides the annular gas channel into an outer gas conduit section and an inner gas conduit section and a first gas flux travels in the outer gas conduit section from a proximal end of the body towards a distal end of the body, opposed to the proximal end, and back towards the proximal end and a second gas flux travels in the inner gas conduit section from one of the proximal end and the distal end towards the other one of the proximal end and the distal end and back towards the one of the proximal end and the distal end.

42. The epitaxial deposition gas injector as claimed in claim 41, wherein the second gas flux travels from the proximal end towards the distal end and back towards the proximal end in the inner gas conduit section.

43. The epitaxial deposition gas injector as claimed in claim 36, wherein the at least one gas inlet is radial to the annular gas channel.

44. A method for injecting a gas flux with a gas injector, the method comprising:
injecting gas in the gas injector at a proximal end thereof;
separating the gas into at least two separated gas fluxes upon entrance into the gas injector, the at least two gas fluxes traveling separately along separated gas paths from the proximal end towards an opposed distal end and back towards the proximal end; and
expelling gas along the gas paths.

45. The method as claimed in claim 44, wherein the gas injector comprises a toroidal gas injector body.

46. The method as claimed in claim 44, wherein the gas is expelled substantially continuously along the gas paths.

47. The method as claimed in claim 44, wherein a first one of the gas fluxes travels in an inner gas conduit defined in the gas injector and a second one of the gas fluxes travels in an outer gas conduit defined in the gas injector.

48. The method as claimed in claim 44, wherein the gas fluxes travel separately towards the distal end in one of outer gas conduit sections and inner gas conduit sections, concentric with the outer gas conduit sections, and back towards the proximal end in the other one of the outer gas conduit sections and the inner gas conduit sections.

49. The method as claimed in claim 44, wherein the gas is injected radially in the gas injector.

50-67. (canceled)

68. A method for injecting a gas flux with a gas injector, the method comprising:
injecting gas in the gas injector;
separating the gas into at least two separated gas fluxes upon entrance into the gas injector, the two gas fluxes traveling separately along separated paths in the gas injector;
expelling the gas along the gas paths in a nozzle having at least one elongated channel and being contiguous to the gas injector; and
expelling the gas at a distal end of the nozzle towards a substrate.

69. The method as claimed in claim 68, further comprising concentrating said gas prior to expelling gas towards the substrate.

70. The method as claimed in claim 68, wherein the gas fluxes travel in separated elongated gas channels in the nozzle.

71. The method as claimed in claim 68, wherein the nozzle comprises at least two concentric and elongated gas channels and the gas fluxes of the gas injector are partially combined in the at least two elongated gas channels of the nozzle and at least two gas fluxes travel separately in the at least two elongated gas channels.

72. The method as claimed in 68, wherein a gas flux direction in the gas injector is substantially normal to a gas flux direction in the at least one elongated channel of the nozzle.

73-93. (canceled)
